(19) United States
(12) Patent Application Publication
(10) Pub. No.: US 2023/0057674 A1
(43) Pub. Date: Feb. 23, 2023

(54) LASER PROCESSING DEVICE AND LASER PROCESSING METHOD

(71) Applicant: HAMAMATSU PHOTONICS K.K., Hamamatsu-shi, Shizuoka (JP)

(72) Inventors: Katsuhiro KOREMATSU, Hamamatsu-shi, Shizuoka (JP); Takeshi SAKAMOTO, Hamamatsu-shi, Shizuoka (JP)

(73) Assignee: HAMAMATSU PHOTONICS K.K., Hamamatsu-shi, Shizuoka (JP)

(21) Appl. No.: 17/795,062

(22) PCT Filed: Dec. 7, 2020
(86) PCT No.: PCT/JP2020/045531

§ 371 Date: Jul. 25, 2022

(30) Foreign Application Priority Data
Jan. 27, 2020 (JP) 2020-011100

(51) Int. Cl. B23K 26/046; B23K 26/067; B23K 26/53; B23K 26/06

(52) U.S. Cl. CPC B23K 26/046; B23K 26/0676; B23K 26/53; B23K 26/0648

(57) ABSTRACT

A control unit performs first processing of irradiating an object with laser light while relatively moving a first converging point and a second converging point along a first line, in a state where a distance between the first converging point and a second converging point is set as a first distance, and performs second processing of irradiating the object with the laser light while relatively moving the first converging point and the second converging point along a second line, in a state where the distance between the first converging point and the second converging point is set to a second distance smaller than the first distance.

### TECHNICAL FIELD

The present disclosure relates to a laser processing device and a laser processing method.

### BACKGROUND ART

Patent Literature 1 discloses a laser processing device. The laser processing device includes a condenser lens, and forms a processed layer on a single crystal member by laser light emitted from the condenser lens. The condenser lens includes a sub-condensing system on which laser light is incident, and a main condensing system on which the laser light emitted from the sub-condensing system is incident and that irradiates the single crystal member with the laser light. The sub-condensing system includes a cylindrical lens array body in which a plurality of cylindrical lenses are integrally arranged, and a cylindrical convex lens through which light from the cylindrical lens array body passes.

In such a laser processing device, laser light incident on the cylindrical lens is branched into a plurality of laser beams, and then is incident on the cylindrical convex lens while forming a converging point, and then parallel beams of which an irradiation plane becomes elongated are incident on the main condensing system. Laser light emitted from the main condensing system is incident as branched laser light on an irradiation target surface of the single crystal member to form a plurality of converging points inside the single crystal member.

### CITATION LIST

### Patent Literature

Patent Literature 1: Japanese Unexamined Patent Publication No. 2014-19120

### SUMMARY OF INVENTION

### Technical Problem

In the laser processing device described above, the formation speed of a processed layer is improved in a manner that the processed layer is formed while forming a plurality of converging points of the laser light. That is, in the above technical field, it is desired to improve the processing speed. On the other hand, in the above technical field, there is a need for processing of cutting out a region (effective region) on the center side of an object by cutting off an annular region (removal region) including an outer edge of the object from the object. The effective region is, for example, a region in which a device is formed. Thus, in the above technical field, it is also desired to suppress deterioration of the quality (that is, the processing quality) of the effective region together.

Therefore, an object of the present disclosure is to provide a laser processing device and a laser processing method capable of achieving both improvement in processing speed and suppression of degradation in processing quality.

### Solution to Problem

The present inventor has obtained the following knowledges by conducting intensive studies in order to solve the above problems. That is, in a case where the effective region is cut out from an object, it is conceivable to perform the following two types of processing. The first processing is processing of forming a modified region at a boundary between the effective region and the removal region by irradiating the boundary between the effective region and the removal region with laser light. The second processing is processing of forming the modified region in the removal region to reach the boundary between the effective region and the removal region from the outer edge of the object, by performing irradiation with laser light to reach the boundary between the effective region and the removal region from the outer edge of the object in order to divide the annular removal region into a plurality of regions and easily remove the removal region.

Here, from the viewpoint of improving the formation speed of the modified region, it is conceivable to form a plurality of rows of modified regions in a thickness direction of an object by forming a plurality of converging points in the thickness direction of the object. In this case, by offsetting the converging points in a proceeding traveling direction (processing proceeding direction) of the converging points, it is possible to increase the development amount of a fracture from the modified region. If the development amount of the fracture increases, the number of rows of modified regions required to cut the object may be reduced in the thickness direction of the object. Thus, in the first processing described above, when the modified region is formed at the boundary between the effective region and the removal region, it is possible to improve the processing speed by offsetting the converging points.

On the other hand, in the second processing described above, if the converging points are offset from each other in the processing traveling direction, for example, when one converging point reaches the boundary between the effective region and the removal region, another converging point offset forward in the processing proceeding direction from the one converging point proceeds into the effective region by a distance corresponding to the offset amount. In this case, the modified region is formed inside the effective region. Therefore, in this case, by reducing the offset amount between the converging points, the modified region formed in the effective region can be reduced, and the deterioration in the quality of the effective region can be suppressed.

On the other hand, when the irradiation of laser light is turned off when the laser light reaches the boundary between the effective region and the removal region, so that another converging point does not proceed in the effective region, the one converging point does not reach the effective region by a distance corresponding to an offset amount. In this case, since the modified region is not formed to reach the effective region, the quality of a cut surface when the object is cut along the boundary between the effective region and the removal region may be deteriorated. Therefore, in this case, by reducing the offset amount between the converging points, it is possible to suppress deterioration in quality of the cut surface.

As described above, by relatively increasing the offset amount between the converging points in the first processing and relatively reducing the offset amount between the converging points in the second processing, it is possible to achieve both improvement in processing speed and suppression of degradation in processing quality. The present disclosure has been made based on such knowledges.

That is, according to the present disclosure, there is provided a laser processing device that forms a modified region by irradiating an object with laser light. The laser processing device includes a support configured to support the object, a laser irradiation unit configured to irradiate the object supported by the support with the laser light while forming a first converging point of the laser light and a second converging point of the laser light located closer to an incident surface side of the laser light in the object than the first converging point, a moving mechanism configured to move at least one of the support and the laser irradiation unit to relatively move the first converging point and the second converging point with respect to the object, and a control unit configured to control the laser irradiation unit and the moving mechanism. The object includes a first portion located on an inner side of the object and a second portion located on an outer side of the first portion and including an outer edge of the object, when viewed from a direction intersecting with the incident surface. In the object, when viewed from the direction intersecting with the incident surface, a first line annularly extending on a boundary between the first portion and the second portion and a second line extending from the outer edge of the object to the inner side of the object in the second portion and reaching the boundary are set. The control unit performs first processing of controlling the laser irradiation unit and the moving mechanism to irradiate the object with the laser light while relatively moving the first converging point and the second converging point along the first line, in a state where a distance between the first converging point and the second converging point in a direction along the first line is set as a first distance, and performs second processing of controlling the laser irradiation unit and the moving mechanism to irradiate the object with the laser light while relatively moving the first converging point and the second converging point along the second line, in a state where a distance between the first converging point and the second converging point in a direction along the second line is set as a second distance smaller than the first distance.

According to the present disclosure, there is provided a laser processing method for forming a modified region by irradiating an object with laser light. The laser processing method includes a laser irradiation step of irradiating the object with the laser light while forming a first converging point of the laser light and a second converging point of the laser light located closer to an incident surface side of the laser light in the object than the first converging point. The object includes a first portion located on an inner side of the object and a second portion located on an outer side of the first portion and including an outer edge of the object, when viewed from a direction intersecting with the incident surface. In the object, when viewed from the direction intersecting with the incident surface, a first line annularly extending on a boundary between the first portion and the second portion and a second line extending from the outer edge of the object to the inner side of the object in the second portion and reaching the boundary are set. The laser irradiation step includes a first irradiation step of irradiating the object with the laser light while relatively moving the first converging point and the second converging point along the first line, in a state where a distance between the first converging point and the second converging point in a direction along the first line is set as a first distance, and a second irradiation step of irradiating the object with the laser light while relatively moving the first converging point and the second converging point along the second line, in a state where a distance between the first converging point and the second converging point in a direction along the second line is set as a second distance smaller than the first distance.

In the device and method, a first line annularly extending on a boundary between a first portion located on an inner side of the object and a second portion located on an outer side of the first portion, and a second line extending from an outer edge of the object to the inner side of the object in the second portion and reaching the boundary are set in the object. Then, in each of processing along the first line and processing along the second line, the object is irradiated with the laser light while two converging points of the laser light are formed on the object. At this time, in the processing along the first line, the distance between the converging points along the first line is set to be relatively large. Therefore, as shown in the above knowledges, it is possible to improve the processing speed. On the other hand, in the processing along the second line, the distance between the converging points along the second line is set to be relatively small. Therefore, as shown in the above knowledges, it is possible to deteriorate the processing quality.

In the laser processing device according to the present disclosure, the control unit may perform the second processing a plurality of times while changing a position of the first converging point and a position of the second converging point in the direction intersecting with the incident surface with respect to one of the second lines. As described above, for the second processing in which the distance between the converging points is set to be relatively small, it is effective to perform the second processing on the one second line a plurality of times.

In the laser processing device according to the present disclosure, the control unit may perform the n-th second processing (n is an integer of 1 or more), and then perform the m-th second processing (in is an integer more than n) in a state where at least one of the first converging point and the second converging point is located at a position between the first converging point and the second converging point in a direction intersecting with the incident surface in the n-th second processing. In this case, it is possible to more densely form the modified region in the direction intersecting with the incident surface, and the processing quality is improved.

In the laser processing device according to the present disclosure, the control unit may perform the n-th second processing (n is an integer of 1 or more), and then perform the (n+1)th second processing in a state where the first converging point is located closer to the incident surface side than the position of the first converging point in a direction intersecting with the incident surface in the n-th second processing. As described above, it is possible to more appropriately form the modified region by performing the second processing while aligning the converging points in order from the side farther from the incident surface.

According to the present disclosure, the laser processing device may further include an input unit configured to receive an input, and a display unit configured to display information. The input unit may receive an input of the first distance before the first processing. The control unit may cause the display unit to display information for urging confirmation of a first input value in a case where the first input value is less than a first threshold value before the first processing, the first input value being an input value of the first distance received by the input unit, and perform the first processing in a case where the first input value is equal to or more than the first threshold value. In this case, in the first processing, it is secured that the first converging point and the second converging point are equal to or more than the threshold value. The development amount of the fracture is reliably increased to improve the processing speed.

In the laser processing device according to the present disclosure, the input unit may receive an input of the second distance before the second processing. The control unit may cause the display unit to display information for urging confirmation of a second input value in a case where the second input value is more than a second threshold value before the second processing, the second input value being an input value of the second distance received by the input unit, and perform the second processing in a case where the second input value is equal to or less than the second threshold value. In this case, in the second processing, it is secured that the distance between the first converging point and the second converging point is equal to or less than the threshold value, and the processing quality is reliably improved.

### Advantageous Effects of Invention

According to the present disclosure, there are provided a laser processing device and a laser processing method capable of achieving both improvement in processing speed and suppression of degradation in processing quality.

### BRIEF DESCRIPTION OF DRAWINGS

FIG. 1 is a schematic diagram illustrating a configuration of a laser processing device according to an embodiment.

FIG. 2 is a schematic diagram illustrating a configuration of a laser irradiation unit illustrated in FIG. 1.

FIG. 3 is a schematic diagram illustrating the configuration of the laser irradiation unit illustrated in FIG. 1.

FIG. 4 is a cross-sectional picture showing a processing result in a case where a distance Dx is set to 0.

FIG. 5 is a cross-sectional picture showing another processing result in a case where the distance Dx is set to 0.

FIG. 6 is a flowchart illustrating an example of a laser processing method according to the present embodiment.

FIG. 7 is a plan view illustrating one step of the laser processing method illustrated in FIG. 6.

FIG. 8 is a diagram illustrating an object illustrated in FIG. 7.

FIG. 9 is a diagram illustrating one step of the laser processing method illustrated in FIG. 6.

FIG. 10 is a diagram illustrating one step of the laser processing method illustrated in FIG. 6.

FIG. 11 is a diagram illustrating an example of a setting screen displayed on an input reception unit.

FIG. 12 is a diagram illustrating one step of the laser processing method illustrated in FIG. 6.

FIG. 13 is a diagram illustrating one step of the laser processing method illustrated in FIG. 6.

FIG. 14 is a picture showing a cross section after a modified region is formed.

FIG. 15 is a diagram illustrating one step of peeling processing.

FIG. 16 is a diagram illustrating one step of the peeling processing.

### DESCRIPTION OF EMBODIMENTS

Hereinafter, an embodiment will be described in detail with reference to the drawings. In the drawings, the same or the corresponding parts are denoted by the same reference signs, and repetitive descriptions thereof will be omitted. In addition, each drawing may illustrate an orthogonal coordinate system defined by an X-axis, a Y-axis, and a Z-axis.

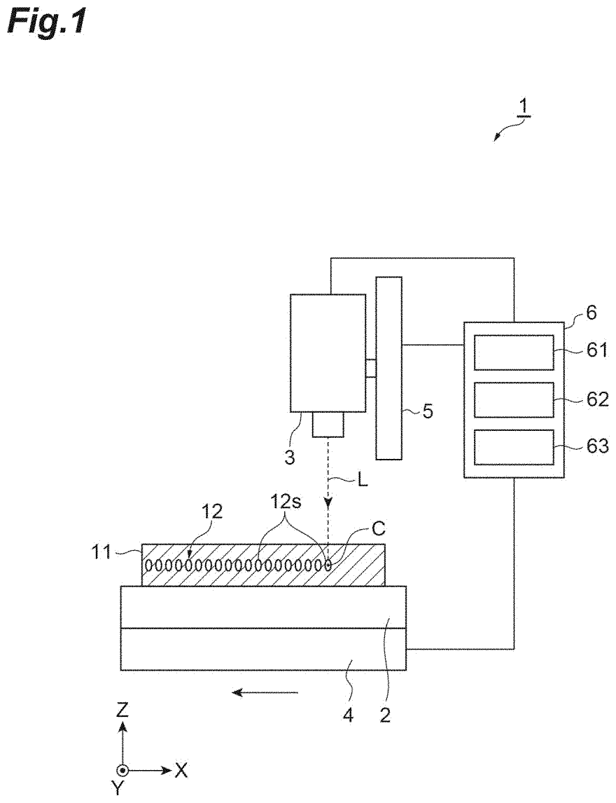

FIG. 1 is a schematic diagram illustrating a configuration of a laser processing device according to an embodiment. As illustrated in FIG. 1, a laser processing device 1 includes a stage (support) 2, a laser irradiation unit 3, drive units (moving units) 4 and 5, and a control unit 6. The laser processing device 1 is a device that forms a modified region 12 on an object 11 by irradiating the object 11 with laser light L.

The stage 2 supports the object 11 by, for example, holding a film attached to the object 11. The stage 2 can rotate around an axis line parallel to a Z-direction as a rotation axis. The stage 2 may be moved along an X-direction and a Y-direction, respectively The X-direction and the Y-direction are referred to as a first horizontal direction and a second horizontal direction that intersect with each other (are perpendicular to each other), and the Z-direction is referred to as a vertical direction.

The laser irradiation unit 3 condenses the laser light L having transparency on the object 11 to irradiate the object 11 with the laser light L. If the laser light L is condensed in the object 11 supported by the stage 2, the laser light L is particularly absorbed at a portion corresponding to a converging point C of the laser light L, and thus a modified region 12 is formed in the object 11.

The modified region 12 is a region in which the density, the refractive index, the mechanical strength, and other physical properties are different from those of the surrounding non-modified region. Examples of the modified region 12 include a melting treatment region, a fracture region, a dielectric breakdown region, and a refractive index change region. The modified region 12 may be formed so that a fracture extends from the modified region 12 to the incident side of the laser light L and the opposite side thereof. Such a modified region 12 and a fracture are used, for example, to cut the object 11.

As an example, if the stage 2 is moved along the X-direction and the converging point C is moved relative to the object 11 along the X-direction, a plurality of modified spots 12s are formed to be arranged in one row along the X-direction. One modified spot 12s is formed by irradiation with the laser light L of one pulse. The modified region 12 in one row is a set of a plurality of modified spots 12s arranged in one row. Adjacent modified spots 12s may be connected to each other or separated from each other, depending on the relative movement speed of the converging point C with respect to the object 11 and the repetition frequency of the laser light L.

The drive unit 4 rotates the stage 2 about an axis line parallel to the Z-direction as a rotation axis. The drive unit 4 may move the stage 2 along the X-direction and the Y-direction, respectively. The drive unit 5 supports the laser irradiation unit 3. The drive unit 5 moves the laser irradiation unit 3 along the X-direction, the Y-direction, and the Z-direction.

The control unit 6 controls the operations of the stage 2, the laser irradiation unit 3, and the drive units 4 and 5. The control unit 6 includes a processing unit 61, a storage unit 62, and an input reception unit (display unit, input unit) 63. The processing unit 61 is configured as a computer device including a processor, a memory, a storage, a communication device, and the like. In the processing unit 61, the processor executes software (program) read into the memory or the like, and controls reading and writing of data in the memory and the storage, and communication by a communication device. The storage unit 62 is, for example, a hard disk or the like, and stores various types of data. The input reception unit 63 is an interface unit that displays various types of information and receives inputs of various types of information from the user. In the present embodiment, the input reception unit 63 constitutes a graphical user interface (GUI).

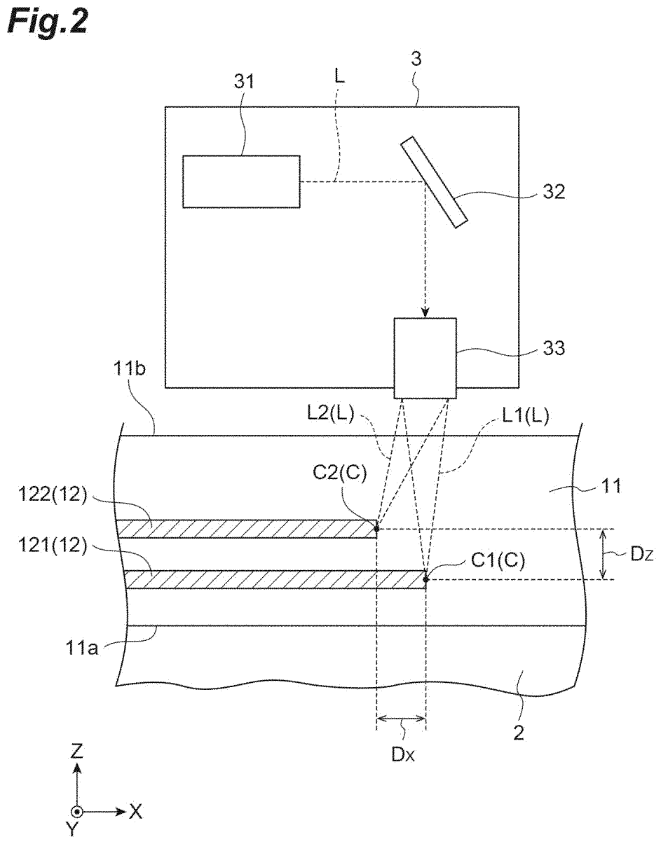

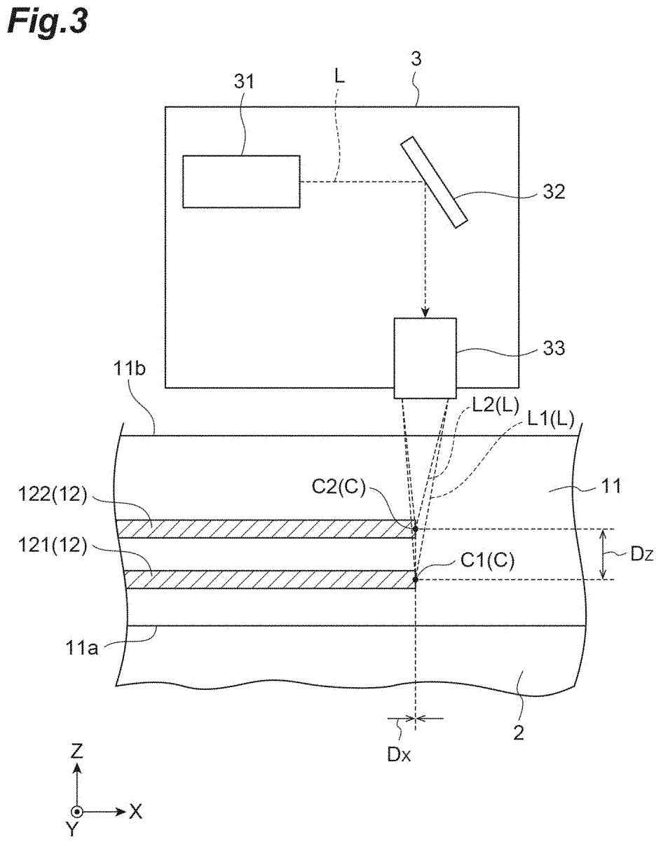

FIGS. 2 and 3 are schematic diagrams illustrating the configuration of the laser irradiation unit illustrated in FIG. 1. As illustrated in FIGS. 2 and 3, the laser irradiation unit 3 includes a light source 31, a spatial light modulator 32, and a condenser lens 33. The light source 31 outputs the laser light L by, for example, a pulse oscillation method. The laser irradiation unit 3 may not include the light source 31, and may be configured to introduce the laser light L from the outside of the laser irradiation unit 3.

The spatial light modulator 32 modulates the laser light L output from the light source 31. The spatial light modulator 32 is a spatial light modulator (SLM) of a reflective liquid crystal (LCOS: Liquid Crystal on Silicon). The condenser lens 33 condenses the laser light L modulated by the spatial light modulator 32. The spatial light modulator 32 includes a liquid crystal layer (not illustrated), and modulates the laser light L in accordance with a modulation pattern displayed on the liquid crystal layer. Here, a branch pattern for branching at least the laser light L into a plurality of (here, two) beams is displayed on the spatial light modulator 32. Thus, the laser light L incident on the spatial light modulator 32 is branched into two beams of laser light L1 and L2 in the spatial light modulator 32 and is condensed by the condenser lens 33 to form a first converging point C1 and a second converging point C2.

This point will be described more specifically. The spatial light modulator 32 branches the laser light L such that the first converging point C1 and the second converging point C2 are formed at positions different from each other at least in the Z-direction intersecting the back surface 11b of the object 11, which is the incident surface of the laser light L. Therefore, by relatively moving the first converging point C1 and the second converging point C2 with respect to the object 11, two rows of modified regions 121 and 122 are formed as the modified regions 12 at positions different from each other in the Z-direction.

The modified region 121 corresponds to the laser light L1 and the first converging point C1 thereof, and the modified region 122 corresponds to the laser light L2 and the second converging point C2 thereof. The first converging point C1 and the modified region 121 are located on the opposite side of the back surface 11b (the front surface 11a side of the object 11) with respect to the second converging point C2 and the modified region 122. In the spatial light modulator 32, a distance Dz (longitudinal branch amount) between the first converging point C1 and the second converging point C2 in the Z-direction is set to be variable.

Furthermore, when branching the laser light L into the laser light L1 and L2, the spatial light modulator 32 can change a distance Dx (lateral branch amount) in the horizontal direction (X-direction in the illustrated example) between the first converging point C1 and the second converging point C2. In the example in FIG. 2, the spatial light modulator 32 sets the distance Dx to be more than 0 such that the first converging point C1 is located in front of the second converging point C2 in the X-direction (processing proceeding direction). In the example in FIG. 3, the spatial light modulator 32 sets the distance Dx between the first converging point C1 and the second converging point C2 to 0.

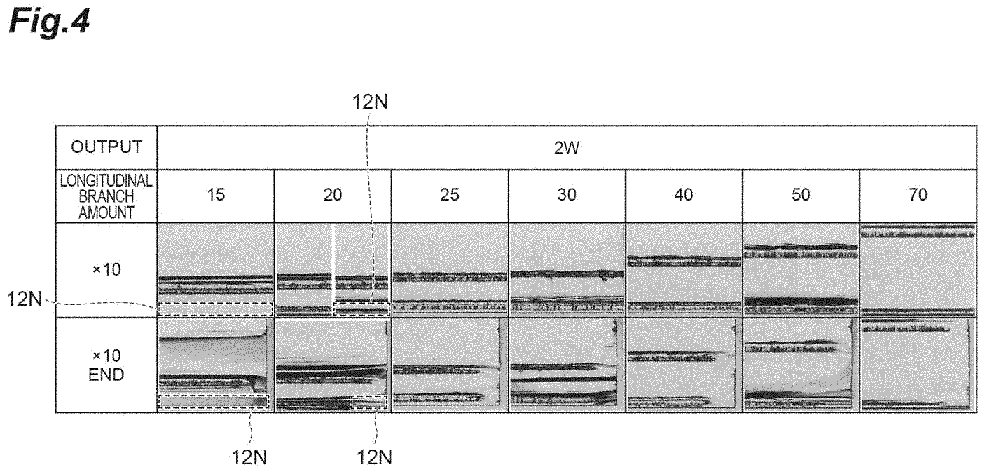

FIG. 4 is a cross-sectional picture showing a processing result in a case where the distance Dx is set to 0. The processing result in FIG. 4 is a processing result in a case where the output of the laser light L is set to 2 W (pulse energy of each beam of laser light L1 and L2 is 10 μJ), the output ratio between the laser light L1 and the laser light L2 is set to 50:50, and the distance Dz (longitudinal branch amount) is changed from 15 μm to 70 μm. As illustrated in FIG. 4, in a case where the distance Dx is set to 0, when the distance Dz is 15 μm and 20 μum, a region 12N in which the modified region 12 (modified region 121) on the front surface 11a side is not partially formed is generated. However, the modified region 121 is formed as a whole by setting the distance Dz to be equal to or more than 25 μm. Specific irradiation conditions of the laser light L1 and L2 in the example in FIG. 4 are a frequency of 80 kHz, a processing speed of 430 mm/s, a pulse pitch of 5.375 μm, and a pulse width of 700 ns.

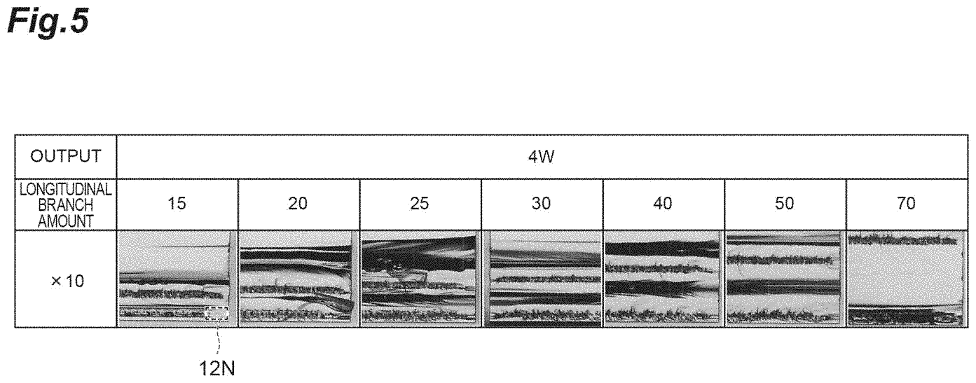

FIG. 5 is a cross-sectional picture showing another processing result in a case where the distance Dx is set to 0. The processing result in FIG. 5 is a processing result in a case where the output of the laser light L is set to 4 W (pulse energy of each beam of laser light L1 and L2 is 20 μJ), the output ratio between the laser light L1 and the laser light L2 is set to 50:50, and the distance Dz is changed from 15 μm to 70 μm. As illustrated in FIG. 5, as compared with the example in FIG. 4, by increasing the output of the laser light L, the region 12N in which the modified region 12 on the front surface 11a side is not formed is reduced, and the modified region 12 is formed substantially entirely for all cases of the distance Dz of 15 μm to 70 μm. Specific irradiation conditions of the laser light L1 and L2 in the example in FIG. 5 are a frequency of 80 kHz, a processing speed of 430 mm/s, a pulse pitch of 5.375 μm, and a pulse width of 700 ns.

According to the knowledge of the present inventor, as the distance Dx is closer to 0, the modified region 12 (modified region 121) on the front surface 11a side is less likely to be formed due to the influence of the second converging point C2 and the modified region 12 (modified region 122) on the back surface 11b side. Thus, as described above, since the modified region 121 is sufficiently formed in a case where the distance Dx is set to 0, it is possible to more reliably form the modified region 121 in a case where the distance Dx is set to be more than 0 (the example in FIG. 2). In particular, by setting the distance Dx to be equal to or more than 8 μm, the influence of the second converging point C2 and the modified region 122 is reduced, and it is possible to reliably form the modified region 121.

As described above, the laser irradiation unit 3 can irradiate the object 11 supported by the stage 2 with the laser light L1 and L2 while forming the first converging point C1 of the laser light L1 and the second converging point C2 of the laser light L2 located closer to the incident surface (back surface 11b) side of the laser light L in the object 11 than the first converging point C1. In particular, in the laser irradiation unit 3, the laser light L can be branched into the laser light L1 and L2, and the distance in each direction of each of the first converging point C1 and the second converging point C2 is set to be variable.

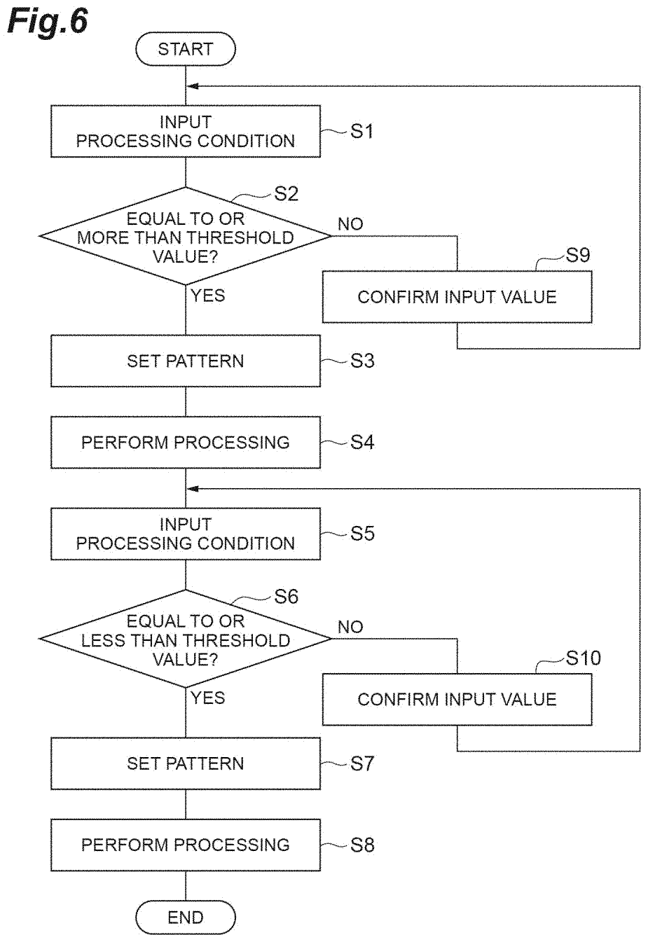

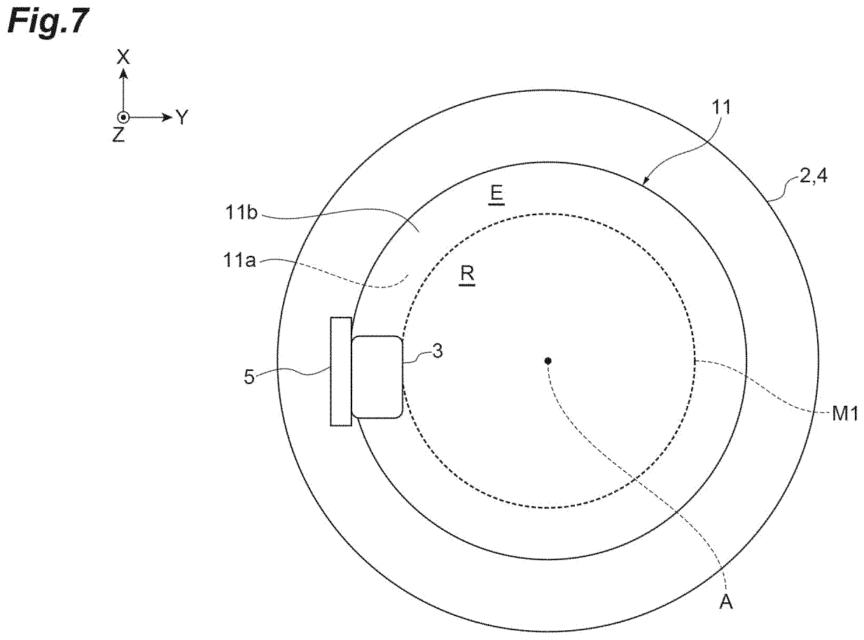

Next, details of the laser processing device will be described with an example of a laser processing method performed by the laser processing device 1. FIG. 6 is a flowchart illustrating an example of the laser processing method according to the present embodiment. Here, the laser processing device 1 performs trimming processing and radiation cutting processing on the object 11. The trimming processing is processing of forming a modified region in order to remove an unnecessary portion from the object 11. The radiation cutting process is a process of forming a modified region in order to separate unnecessary portions to be removed in the trimming processing. Here, first, as illustrated in FIG. 7, the object 11 is supported by the stage 2.

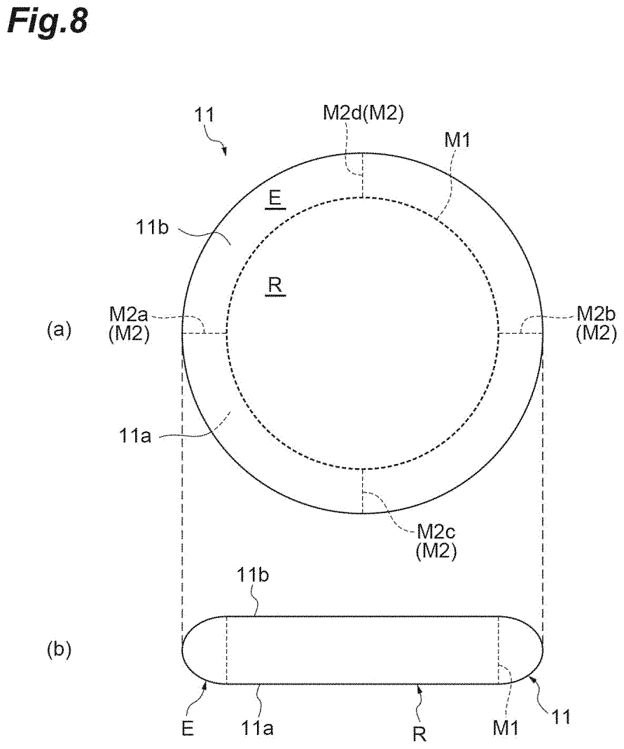

FIG. 8 is a diagram illustrating the object illustrated in FIG. 7. (a) of FIG. 8 is a plan view, and (b) of FIG. 8 is a side view. As illustrated in FIGS. 7 and 8, the object 11 here includes a semiconductor wafer formed in, for example, a disc shape. However, the object 11 is not particularly limited, and may be formed in various shapes by various materials. Functional elements (not illustrated) as an example are formed on the front surface 11a of the object 11. The functional elements are, for example, light-receiving elements, such as photodiodes, light-emitting elements, such as laser diodes, circuit elements, such as memories, or the like. The object 11 is supported by the stage 2 such that the back surface 11b on the opposite side of the front surface 11a faces the laser irradiation unit 3 side.

An effective region R (first portion) and a removal region E (second portion) are set in the object 11. The effective region R is a device region in which the functional element is formed. The effective region R is, for example, a disc-shaped portion including a central portion when viewed from a thickness direction (being direction from the front surface 11a toward the back surface 11b, Z-direction) of the object 11. That is, the effective region R is a portion located closer to the inner side of the object 11 than the removal region E.

The removal region E is a portion that is located on the outer side of the effective region R in the object 11 and includes the outer edge of the object 11. Here, the removal region E is a portion of the object 11 other than the effective region R and is an annular portion surrounding the effective region R when viewed from the Z-direction. The removal region E includes a peripheral portion (bevel portion on the outer edge) of the object 11 when viewed from the Z-direction. The removal region E is a radiation cut region to be subjected to the radiation cutting processing.

A line (first line) M1 and a line (second line) M2 are set in the object 11. The line M1 is a line on which a modified region is scheduled to be formed by the trimming processing. The line M1 annularly extends on a boundary between the effective region R and the removal region E, when viewed from the Z-direction. The line M1 coincides with the outer edge (inner edge of the removal region E) of the effective region R when viewed from the Z-direction. That is, the line M1 indicates the boundary between the effective region R and the removal region E. The line M2 is a line on which a modified region is scheduled to be formed by the radiation cutting processing. The line M2 extends linearly (radially) along a radial direction of the object 11, when viewed from the Z-direction.

The line M2 extends from the outer edge of the object 11 to the inner side of the object 11 in the removal region E when viewed from the Z-direction, and reaches the boundary between the effective region R and the removal region E. The line M2 does not reach the inside of the effective region R and is stopped at an intersection with the line M1. Among the lines M2, the line M2a and the line M2b are arranged on a straight line. Among the lines M2, the line M2c and the line M2d are arranged on a straight line in a direction intersecting (perpendicular to) the lines M2a and M2b. The lines M1 and M2 can be set by the control unit 6. As an example, the lines M1 and M2 are virtual lines or designated by coordinates.

First, trimming processing is performed on the object 11 as described above. For this purpose, first, the control unit 6 receives an input of processing conditions for trimming processing (Step S1). More specifically, in Step S1, the control unit 6 causes the input reception unit 63 to display information for urging the input of the processing conditions. The input reception unit 63 receives the input of the processing conditions. At this time, the input reception unit 63 receives at least an input of the distance Dx (first distance) in the trimming processing. An example of an input value of the distance Dx is 110 μm.

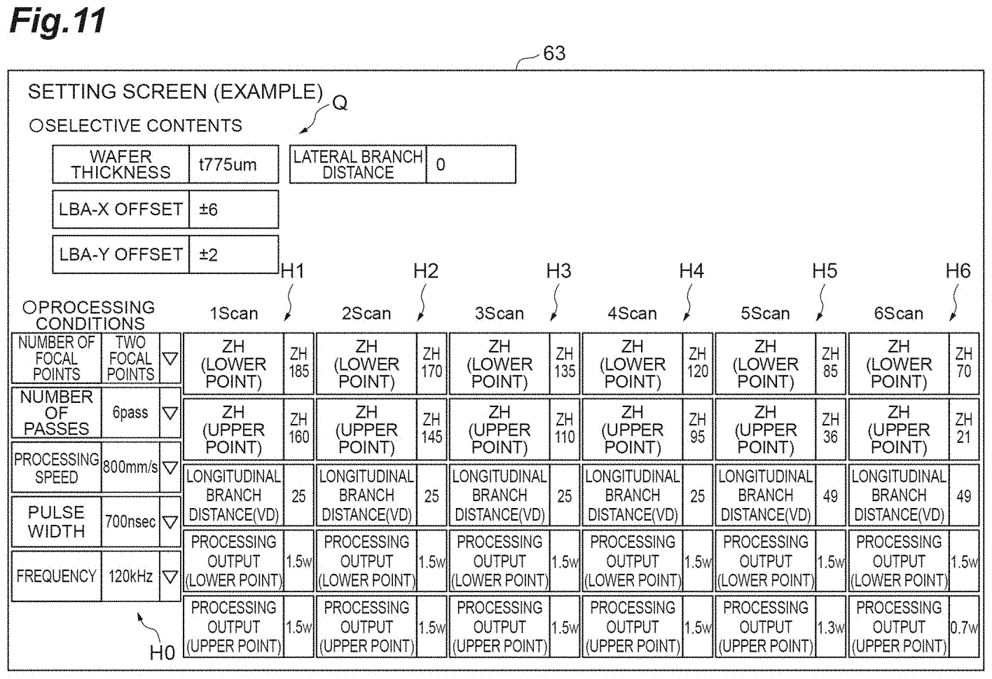

In addition, the input reception unit 63 can receive an input of each condition similarly to each value in FIG. 11 described later. That is, as an example, the input reception unit 63 receives inputs of the number of focal points, the number of passes, a processing speed, a pulse width, and a frequency as basic processing conditions. The number of focal points is the number of branches of the laser light L by the spatial light modulator 32, and is mainly 2 here. The number of passes is the number of times of trimming processing on the line M1, that is, the number of times of first processing (described later) on the line M1. The number of passes is the number of times of scanning of the laser light L1 and L2, and is 4 as an example. Therefore, in the trimming processing, the modified regions 12 of the number of rows corresponding to (the number of focal points)×(the number of passes) are formed in the Z-direction.

Furthermore, the input reception unit 63 can receive an input of detailed processing conditions in each scanning Here, since 4 is input as the number of passes, the input reception unit 63 can receive the input of the processing condition in each of the four times of scanning An example of the input value in each time of scanning is as follows.

[First Scanning]

ZH (lower point): 176.

ZH (upper point): 160.

Processing output (lower point): 2.6 W.

Processing output (upper point): 2.6 W.

Frequency: 120 kHz.

Speed: 800 mm/s

Pulse width: 700 nsec.

Longitudinal branch distance (VD): 16.

[Second Scanning]

ZH (lower point): 140.

ZH (upper point): 115.

Processing output (lower point): 2.6 W.

Processing output (upper point): 2.6 W.

Frequency: 120 kHz.

Speed: 800 mm/s

Pulse width: 700 nsec.

Longitudinal branch distance (VD): 25.

[Third Scanning]

ZH (lower point): 78.

ZH (upper point): 40.

Processing output (lower point): 2.6 W.

Processing output (upper point): 2.6 W.

Frequency: 120 kHz.

Speed: 800 mm/s

Pulse width: 700 nsec.

Longitudinal branch distance (VD): 38.

[Fourth Scanning] (Here, One Focal Point)

ZH (lower point): 22.

ZH (upper point): -.

Processing output (lower point): 2.6 W.

Processing output (upper point): -

Frequency: 120 kHz.

Speed: 800 mm/s

Pulse width: 700 nsec.

Longitudinal branch distance (VD): -.

ZH (lower point) corresponds to the position of the first converging point C1 in the Z-direction. ZH (upper point) corresponds to the position of the second converging point C2 in the Z-direction. Since ZH (lower point) and ZH (upper point) are based on the back surface 11b that is the incident surface of the laser light L1 and L2, the more the numerical value, the farther the distance from the back surface 11b. The longitudinal branch distance (VD) is the distance Dz and corresponds to a difference between ZH (lower point) and ZH (upper point). The processing output (lower point) is the output of the laser light L1, and the processing output (upper point) is the output of the laser light L2. Here, the same value is input for the processing output (lower point) and the processing output (upper point). Therefore, the output ratio between the laser light L1 and the laser light L2 is set to 50:50.

In the subsequent step, the control unit 6 determines whether or not a first input value that is the input value of the distance Dx received by the input reception unit 63 is equal to or more than a first threshold value (Step S2). The first threshold value is, for example, 50 μm. In a case where the first input value of the distance Dx is equal to or more than the first threshold value as a result of the determination in Step S2 (Step S2: YES), the control unit 6 sets (generates) a branch pattern corresponding to the first input value of the distance Dx (Step S3). In a case where the first input value of the distance Dx is not equal to or more than the first threshold value as a result of the determination in Step S2 (Step S2: NO), the control unit 6 causes the input reception unit 63 to display information for urging confirmation of the first input value (Step S9), and proceeds to Step Si to urge re-input of the distance Dx.

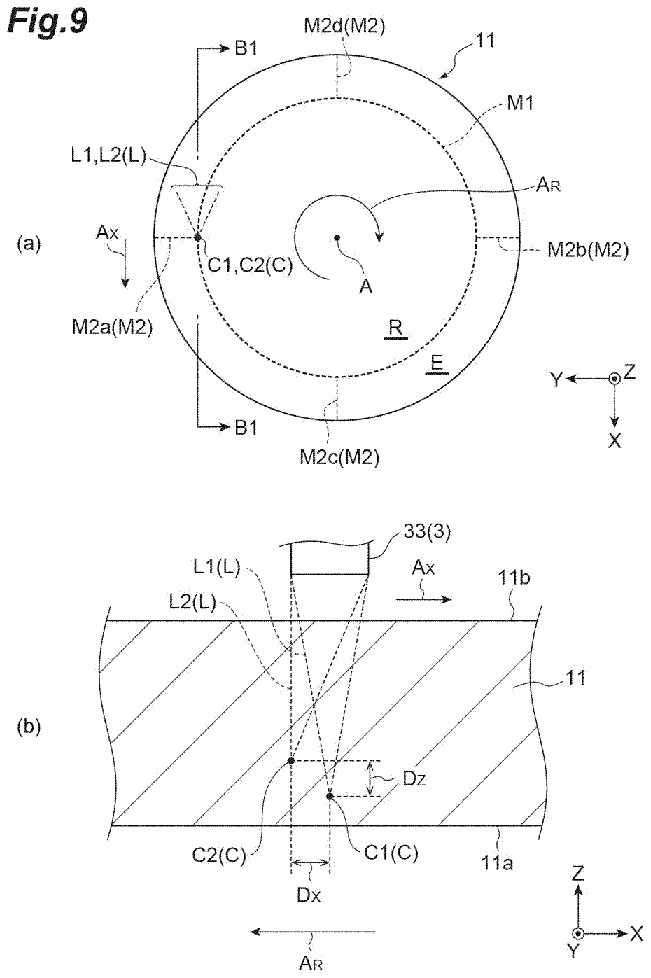

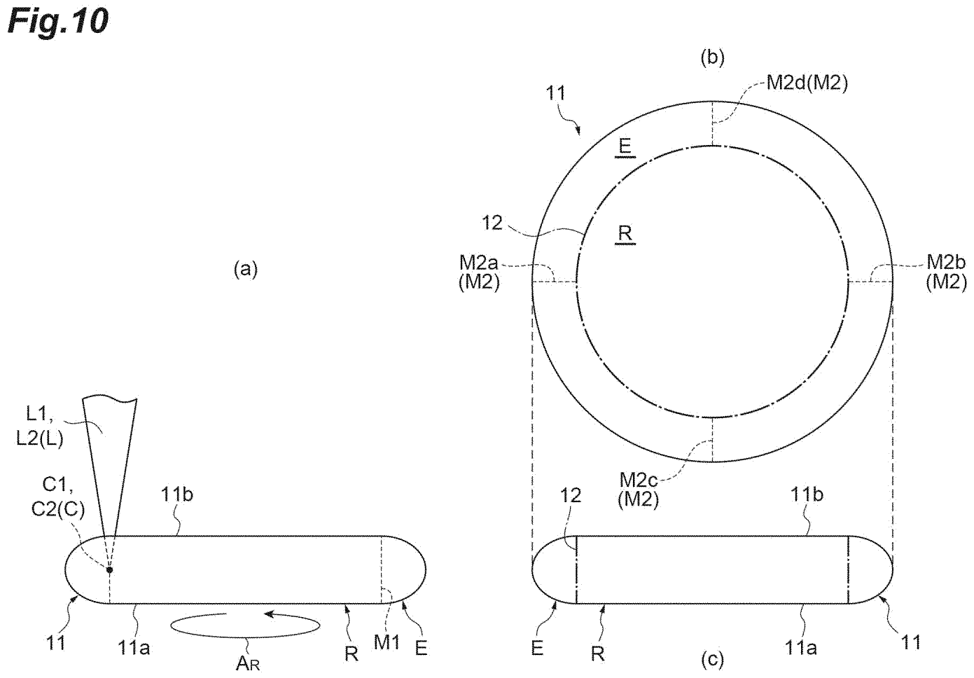

In the subsequent step, the control unit 6 actually performs processing (Step S4: laser irradiation step, first irradiation step). More specifically, as illustrated in (a) of FIGS. 9 and 10, the control unit 6 moves the laser irradiation unit 3 by controlling the drive unit 5 (and/or the drive unit 4) such that the first converging point C1 and the second converging point C2 are located on the line M1 when viewed from the Z-direction. At the same time, the control unit 6 controls the spatial light modulator 32 to cause the spatial light modulator 32 to display the branch pattern such that the first converging point C1 is located in front of the second converging point C2 in the X-direction by the distance Dx and such that the second converging point C2 is located closer to the back surface 11b side than the first converging point C1 by the distance Dz. (a) of FIG. 9 is a plan view, and (b) of FIG. 9 is a cross-sectional view taken along line B1-B1 in (a) of FIG. 9. (a) and (c) of FIG. 10 are side views, and (b) of FIG. 10 is a plan view.

Then, in Step S4, the control unit 6 controls the drive unit 4 to rotate the stage 2 around a rotation axis A, and controls the laser irradiation unit 3 to irradiate the object 11 with the laser light L1 and L2. The rotation axis A is the center of the object 11 and the line M1. Thus, the first converging point C1 and the second converging point C2 are relatively moved with respect to the object 11 in a direction along the line M1, which is opposite to a rotation direction AR of the stage 2 (here, the X-direction). That is, here, the distance Dx is a distance between the first converging point C1 and the second converging point C2 in the direction along the line M1 (tangential direction of the line M1).

Here, the control unit 6 controls the start and stop of the irradiation with the laser light L1 and L2 based on a rotation angle of the stage 2, while rotating the stage 2 at a constant rotation speed. The control unit 6 irradiates the object 11 with the laser light L1 and L2 over the entire circumference of the line M1. Thus, the modified region 12 (modified region 121) corresponding to the laser light L1 and the first converging point C1 and the modified region 12 (modified region 122) corresponding to the laser light L2 and the second converging point C2 are formed on the line M1 at least inside the object 11.

That is, in the laser processing device 1, the drive units 4 and 5 are moving mechanisms that move the stage 2 to relatively move the first converging point C1 and the second converging point C2 with respect to the object 11. In addition, the control unit 6 controls such the laser irradiation unit 3 and the drive units 4 and 5. The control unit 6 performs first processing of controlling the laser irradiation unit 3 and the drive units 4 and 5 to irradiate the object 11 with the laser light L while relatively moving the first converging point C1 and the second converging point C2 among the line M1, in a state where the distance Dx between the first converging point C1 and the second converging point C2 in the direction along the line M1 is set to the first input value (first distance).

The control unit 6 controls the drive unit 5 to move the laser irradiation unit 3 in the Z-direction. In this manner, the control unit 6 can perform the first processing a plurality of times (the number of passes described above) while changing the positions of the first converging point C1 and the second converging point C2 in the Z-direction. Thus, as illustrated in (b) and (c) of FIG. 10, the modified region 12 and a fracture extending from the modified region 12 can be formed from the front surface 11a to the back surface 11b of the object 11. The modified region 12 and the fracture may reach at least either the front surface 11a or the back surface 11b, or may not reach at least either the front surface 11a or the back surface 11b. Thus, the trimming processing is completed. Then, the radiation cutting processing is performed.

In the subsequent step, the control unit 6 receives an input of processing conditions for the radiation cutting processing (Step S5). More specifically, in Step S5, the control unit 6 causes the input reception unit 63 to display information for urging the input of the processing conditions. The input reception unit 63 receives the input of the processing conditions. At this time, the input reception unit 63 receives at least an input of the distance Dx (second distance) in the radiation cutting processing. In addition, the input reception unit 63 receives inputs of various processing conditions. This point will be described in detail.

FIG. 11 is a diagram illustrating an example of a setting screen displayed on the input reception unit. As illustrated in FIG. 11, here, inputs of a wafer thickness, an LBA-X offset, an LBA-Y offset, and the lateral branch distance (distance Dx) are received as selective contents Q. The LBA-X offset is an offset amount in the X-direction (direction along the line M1) between the center of a spherical aberration correction pattern among various patterns displayed on the spatial light modulator 32 and the center of the incident pupil plane of the condenser lens 33. Similarly, the LBA-Y offset is an offset amount in the Y-direction (direction intersecting with the line M1) between the center of the spherical aberration correction pattern and the center of the incident pupil plane of the condenser lens 33. Here, 0 is input as the lateral branch distance (distance Dx).

The input reception unit 63 also receives inputs of the number of focal points, the number of passes, a processing speed, a pulse width, and a frequency as basic processing conditions H0. The number of focal points is the number of branches of the laser light L by the spatial light modulator 32, and is 2 here. The number of passes is the number of times of radiation cutting processing on one line M2, that is, the number of times of second processing on one line M2, and is the number of times of scanning of the laser light L1 and L2. Therefore, in the radiation cutting processing, the modified regions 12 of the number of rows corresponding to (the number of focal points)×(the number of passes) are formed in the Z-direction. The processing speed is a speed of relative movement of the first converging point C1 and the second converging point C2 with respect to the object 11.

Furthermore, the input reception unit 63 receives an input of detailed processing conditions in each scanning Here, since 6 is input as the number of passes, the input reception unit 63 receives the input of the processing conditions H1 to H6 in each of the six times of scanning In the processing conditions H1 to H6, ZH (lower point) corresponds to the position of the first converging point C1 in the Z-direction. ZH (upper point) corresponds to the position of the second converging point C2 in the Z-direction. Since ZH (lower point) and ZH (upper point) are based on the back surface 11b that is the incident surface of the laser light L1 and L2, the more the numerical value, the farther the distance from the back surface 11b.

The longitudinal branch distance (VD) is the distance Dz and corresponds to a difference between ZH (lower point) and ZH (upper point). The processing output (lower point) is the output of the laser light L1, and the processing output (upper point) is the output of the laser light L2. Here, the same value is input for the processing output (lower point) and the processing output (upper point). Therefore, the output ratio between the laser light L1 and the laser light L2 is set to 50:50.

In the subsequent step, the control unit 6 determines whether or not a second input value that is the input value of the distance Dx received (for radiation cutting) by the input reception unit 63 is equal to or less than a second threshold value (Step S6). The second threshold value is a value less than the first threshold value in the trimming processing (first processing), and is, for example, 15 μm. In a case where the second input value of the distance Dx is equal to or less than the second threshold value as a result of the determination in Step S6, the control unit 6 sets (generates) a branch pattern corresponding to the second input value of the distance Dx (Step S7). In a case where the second input value of the distance Dx is not equal to or less than the second threshold value as a result of the determination in Step S6 (Step S6: NO), the control unit 6 causes the input reception unit 63 to display information for urging confirmation of the second input value (Step S10), and proceeds to Step S5 to urge re-input of the distance Dx.

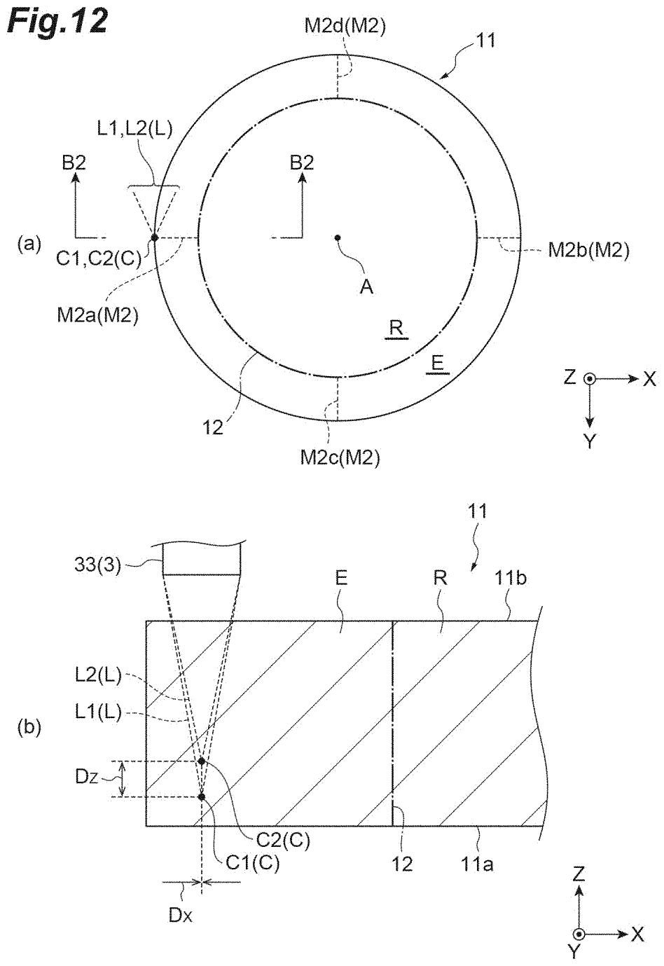

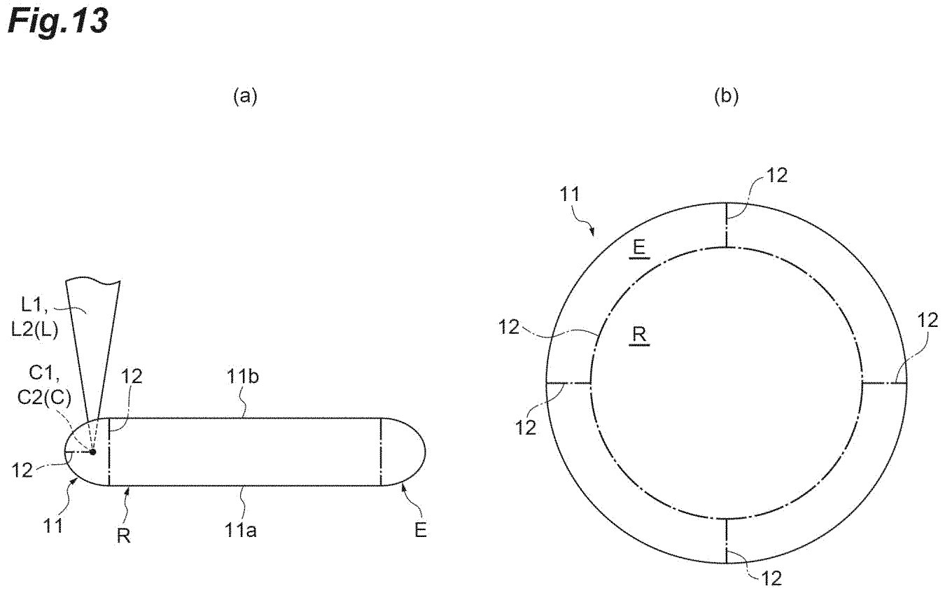

In the subsequent step, the control unit 6 actually performs processing (Step S8: laser irradiation step, second irradiation step). More specifically, as illustrated in (a) of FIGS. 12 and 13, the control unit 6 moves the laser irradiation unit 3 by controlling the drive unit 5 (and/or the drive unit 4) such that the first converging point C1 and the second converging point C2 enter into the object 11 from the outside of the object 11 and then move on the line M2 when viewed from the Z-direction. At the same time, the control unit 6 controls the spatial light modulator 32 to cause the spatial light modulator 32 to display the branch pattern such that the second converging point C2 is located closer to the back surface 11b side than the first converging point C1 by the distance Dz. Here, as described above, 0 is input as the second input value of the distance Dx. Thus, the position of the first converging point C1 and the position of the second converging point C2 along the line M2 coincide with each other. (a) of FIG. 12 is a plan view, and (b) of FIG. 12 is a cross-sectional view taken along line B2-B2 in (a) of FIG. 12. (a) of FIG. 13 is a side view, and (b) of FIG. 13 is a plan view.

Here, the control unit 6 irradiates the object 11 with the laser light L1 and L2 while relatively moving the first converging point C1 and the second converging point C2 from the end portion on the outer edge side of the object 11 to the inside of the object 11, for one line M2a of the lines M2. The object 11 is located such that the line M2a is along the X-direction. Thus, the first converging point C1 and the second converging point C2 are relatively moved in the X-direction. That is, here, the distance Dx is a distance between the first converging point C1 and the second converging point C2 in the X-direction along the line M2a (here, 0).

As described above, the control unit 6 performs the second processing of controlling the laser irradiation unit 3 and the drive unit 5 (and/or drive unit 4) to irradiate the object 11 with the laser light L1 and L2 while relatively moving the first converging point C1 and the second converging point C2 along the line M2, in a state where the distance Dx between the first converging point C1 and the second converging point C2 in the direction along the line M2 (line M2a) is set to the second input value (second distance) less than the distance Dx (first distance) in the trimming processing.

The control unit 6 continues the relative movement between the first converging point C1 and the second converging point C2. The control unit 6 turns off the irradiation with the laser light L1 and L2 when the first converging point C1 and the second converging point C2 reach the intersection of the line M2a and the line M1. Then, when the positions (positions in the X-direction) at which the first converging point C1 and the second converging point C2 are formed reaches an intersection between the line M1 and another line M2b located on the same straight line as the line M2a among the lines M2, the control unit 6 turns on the irradiation with the laser light L1 and L2 and irradiates the object 11 with the laser light L1 and L2 while relatively moving the first converging point C1 and the second converging point C2 on the line M2b in the X-direction, similarly to the line M2a. Furthermore, the control unit 6 similarly performs the second processing for still other lines M2c and M2d among the lines M2.

As described above, here, 6 is input as the number of times of scanning (the number of passes) of the laser light L1 and L2 per line M2. Thus, the control unit 6 controls the drive unit 5 to move the laser irradiation unit 3 in the Z-direction with respect to one line M2. In this manner, the control unit 6 performs the second processing a plurality of times (here, sixth times) while changing the positions of the first converging point C1 and the second converging point C2 in the Z-direction.

In particular, when the control unit 6 performs the second processing on one line M2 a plurality of times, the control unit 6 can perform the n-th second processing (n is an integer of 1 or more), and then perform the m-th second processing (in is an integer more than n) in a state where at least one of the first converging point C1 and the second converging point C2 is located at a position between the first converging point C1 and the second converging point C2 in the Z-direction in the n-th second processing.

Referring to FIG. 11, a value between ZH (lower point) and ZH (upper point) in the first scanning is input as a value of ZH (lower point) in the second scanning Furthermore, a value less than ZH (upper point) in the first scanning is input as a value of ZH (upper point) in the second scanning The relationship between the fourth scanning and the third scanning and the relationship between the sixth scanning and the fifth scanning are similar.

That is, in the example in FIG. 11, after performing the first, third, and fifth second processing, the control unit 6 performs the second, fourth, and sixth second processing in a state where only the first converging point C1 is located at a position between the first converging point C1 and the second converging point C2 in the Z-direction in the first, third, and fifth second processing.

In other words, in the example in FIG. 11, after performing the (2n−1)th second processing (n is an integer of 1 or more), the control unit 6 performs the (2n)th second processing in a state where the first converging point C1 is located between the position of the first converging point C1 and the position of the second converging point C2 in the Z-direction in the (2n−1)th second processing, and the second converging point C2 is located closer to the back surface 11b side than the position of the second converging point C2 in the Z-direction in the (2n−1)th second processing.

Furthermore, in the example in FIG. 11, focusing on each of the first converging point C1 and the second converging point C2, the position in the Z-direction is sequentially moved to the back surface 11b side from the first time to the sixth time. That is, in the example in FIG. 11, after performing the n-th second processing (n is an integer of 1 or more), the control unit 6 performs the (n+1)th second processing in a state where the first converging point C1 is located closer to the back surface 11b side than the position of the first converging point C1 in the Z-direction in the n-th second processing. In addition, after performing the n-th second processing (n is an integer of 1 or more), the control unit 6 performs the (n+1)th second processing in a state where the second converging point C2 is located to the back surface 11b side than the position of the second converging point C2 in the Z-direction in the n-th second processing.

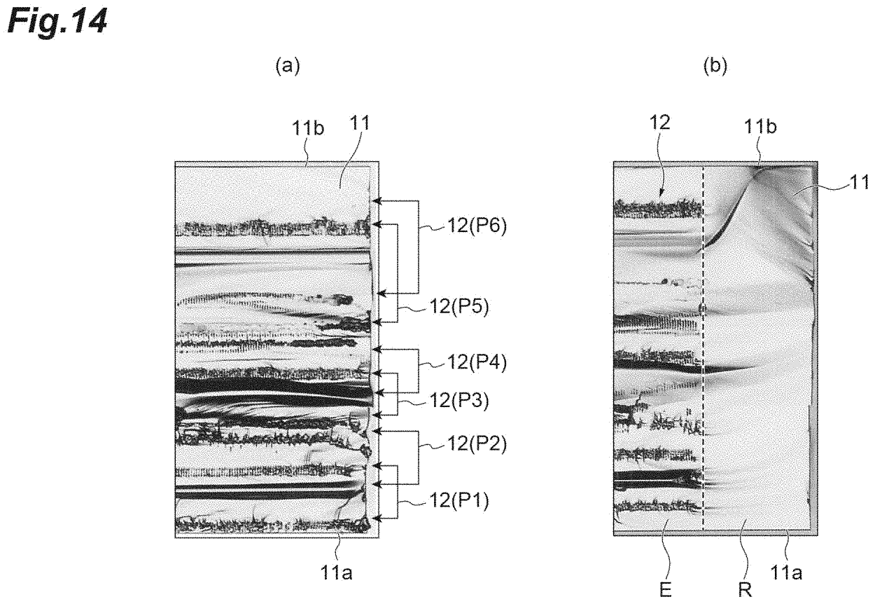

As described above, as illustrated in (b) of FIG. 13, the modified region 12 is formed for all the lines M2. In particular, as illustrated in (a) of FIG. 14, the modified region 12 (modified region 121) on the front surface 11a side in the second scanning P2 is formed between a pair of modified regions 12 (modified regions 121 and 122) formed in the first scanning P1. The modified region 12 on the front surface 11a side in the fourth scanning P4 is formed between a pair of modified regions 12 formed in the third scanning P3. In addition, the modified region 12 on the front surface 11a side in the sixth scanning P2 is formed between a pair of modified regions 12 formed in the fifth scanning P5.

Thus, a fracture extending from the modified region 12 and the modified region 12 is formed from the front surface 11a to the back surface 11b of the object 11. The modified region 12 and the fracture may reach at least either the front surface 11a or the back surface 11b, or may not reach at least either the front surface 11a or the back surface 11b. FIG. 14 is a picture showing a cross section after the modified region is formed.

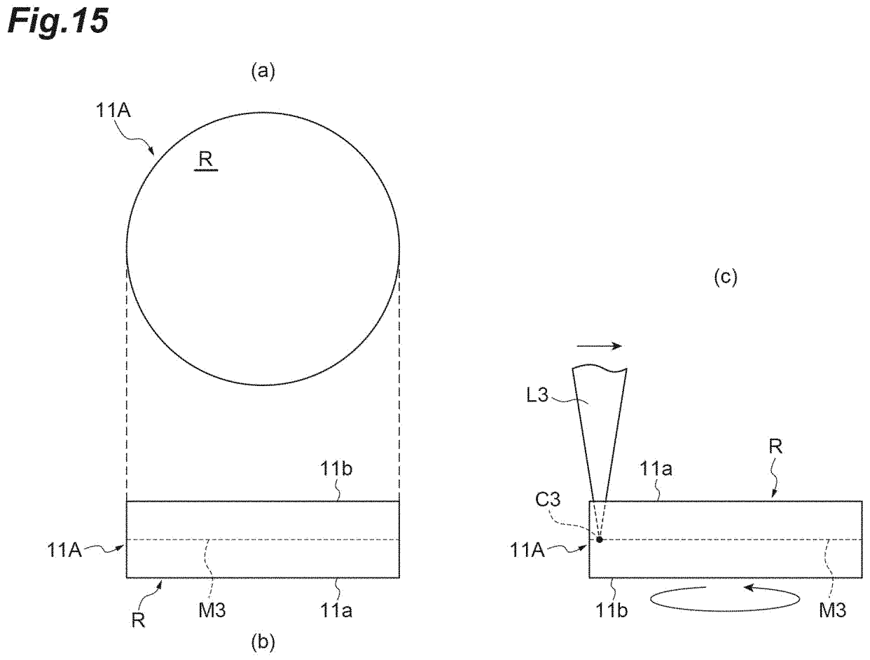

Then, as illustrated in FIG. 15, an object 11A is formed from the object 11 in a manner that the removal region E is cut and removed with the modified region 12 on the line M1 as a boundary, for example, by a jig or air (the effective region R is cut out). Then, the laser processing device 1 can perform peeling processing. Subsequently, peeling processing will be described. (a) of FIG. 15 is a plan view, (b) is a side view, and (c) is a side view.

As illustrated in FIG. 15, a virtual plane M3 is set as a peeling-scheduled plane in the object 11A. The virtual plane M3 is a plane on which the modified region is scheduled to be formed by the peeling processing. The virtual plane M3 is a plane facing the back surface 11b of the object 11A, which is a laser light incident surface. The virtual plane M3 is parallel to the back surface 11b, and is, for example, circular-shaped. The virtual plane M3, which is a virtual region, is not limited to a plain surface but may be a curved surface or a three-dimensional surface. The virtual plane M3 can be set by the control unit 6. The virtual plane M3 may be designated by coordinates.

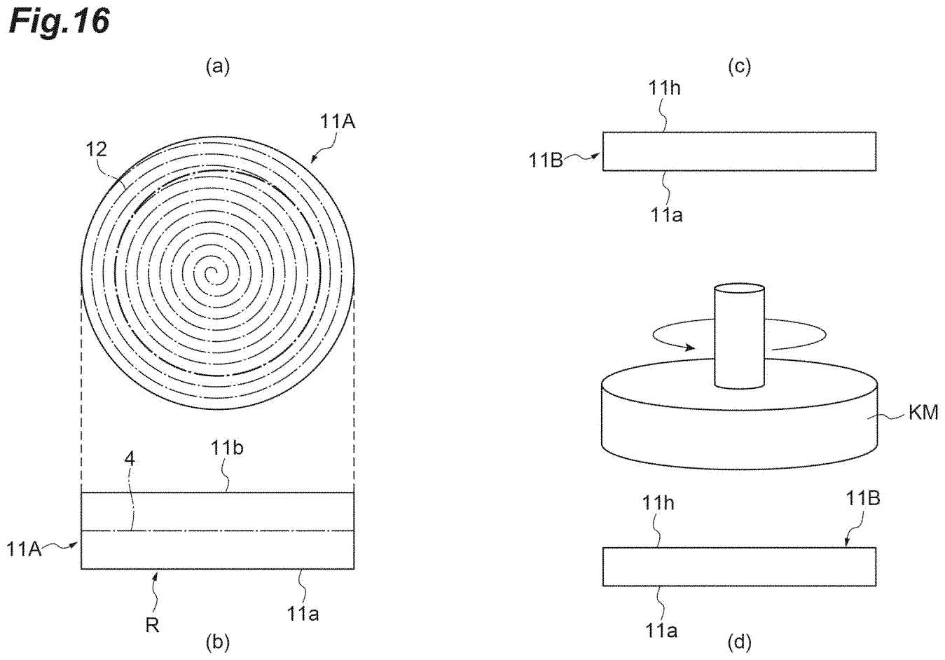

In the peeling processing, the control unit 6 controls the drive unit 4 to perform irradiation with laser light L3 from the laser irradiation unit 3 while rotating the stage 2 at a constant rotation speed. At the same time, the control unit 6 controls the drive unit 5 to move the laser irradiation unit 3 such that the converging point C3 of the laser light L3 moves inward from the outer edge side of the virtual plane M3. As a result, as illustrated in (a) of FIG. 16, the modified region 12 is formed as a modified region of a spiral shape (involute curve) extending around the position of the rotation axis A (see FIG. 9) along the virtual plane M3 inside the object 11A. The formed modified region 12 includes a plurality of modified spots. (a) of FIG. 16 is a plan view, and the other is a side view.

Subsequently, as illustrated in (b) and (c) of FIG. 16, a portion of the object 11A is peeled off along the modified region 12 extending over the virtual plane M3 as a boundary, for example, by a suction jig. The portion of the object 11A may be peeled off on the stage 2 or may be peeled off after being moved to an area specific for peeling. The portion of the object 11A may be peeled off by using air blast or a tape. In a case where it is not possible to peel off the portion of the object 11A solely by an external stress applied thereto, the modified region 12 may be selectively etched with an etching solution (KOH or TMAH) that reacts with the object 11A. This allows the portion of the object 11A to be peeled off easily. As illustrated in (b) of FIG. 16, a peeling surface 11h of the object 11A is subjected to finish grinding or polishing by an abrasive material KM, such as a grindstone. In a case where the portion of the object 11A is peeled off by etching, this polishing can be simplified. Through the above processing, a semiconductor device 11B is obtained.

As described above, in the laser processing device 1 and the laser processing method thereof, the line M1 extending annularly on the boundary between the effective region R located inside the object 11 and the removal region E located outside the effective region R and the line M2 that extends from the outer edge of the object 11 to the inside of the object 11 and reaches the boundary in the removal region E are set in the object 11. Then, in each of the processing (trimming processing) along the line M1 and the processing (radiation cutting processing) along the line M2, the object 11 is irradiated with the laser light L while the first converging point C1 and the second converging point C2 of the laser light L are formed on the object 11. At this time, in the processing along the line M1, the distance Dx between the first converging point C1 and the second converging point C2 along the line M1 is set to be relatively large. Therefore, it is possible to improve the processing speed. On the other hand, in the processing along the line M2, the distance Dx between the first converging point C1 and the second converging point C2 along the line M2 is set to be relatively small. Therefore, it is possible to deteriorate the processing quality.

(b) of FIG. 14 is a picture showing a cross section of a boundary portion between the effective region R and the removal region E. As illustrated in (b) of FIG. 14, by setting the distance Dx between the first converging point C1 and the second converging point C2 to be relatively small (0 as an example) in the processing along the line M2, the end portion of the modified region 12 corresponding to the first converging point C1 and the end portion of the modified region 12 corresponding to the second converging point C2 are aligned. That is, in this case, an occurrence of a situation in which one of the first converging point C1 and the second converging point C2 enters into the effective region R and the modified region 12 is formed in the effective region R, and in which the other of the first converging point C1 and the second converging point C2 does not reach the effective region R and a non-modified region is generated in the removal region E is suppressed.

In the laser processing device 1, the control unit 6 can perform the second processing a plurality of times while changing the position of the first converging point C1 and the position of the second converging point C2 in the Z-direction intersecting the back surface 11b, for one line M2. As described above, it is effective to perform at least the second processing in which the distance Dx between the first converging point C1 and the second converging point C2 is set to be relatively small, a plurality of times for one line M2.

In addition, in the laser processing device 1, the control unit 6 can perform the n-th second processing (n is an integer of 1 or more), and then perform the m-th second processing (in is an integer more than n) in a state where at least one of the first converging point C1 and the second converging point C2 is located at the position between the first converging point C1 and the second converging point C2 in the Z-direction in the n-th second processing. In this case, it is possible to more densely form the modified region 12 in the Z-direction, and the processing quality is improved.

In addition, in the laser processing device 1, after performing the n-th second processing (n is an integer of 1 or more), the control unit 6 can perform the (n+1)th second processing in a state where the first converging point C1 is located to the back surface 11b side than the position of the first converging point C1 in the Z-direction in the n-th second processing. As described above, it is possible to more appropriately form the modified region 12 by performing the second processing while aligning the converging points in order from the side farther from the back surface 11b.

The laser processing device 1 further includes the input reception unit 63 that receives an input and displays information. Before the first processing, the input reception unit 63 receives the input of the distance Dx in the first processing. Before the first processing, in a case where the first input value that is the input value of the distance Dx received by the input reception unit 63 is less than the first threshold value, the control unit 6 causes the input reception unit 63 to display information for urging confirmation of the first input value. In addition, in a case where the first input value is equal to or more than the first threshold value, the control unit 6 performs the first processing. Therefore, in the first processing, it is secured that the distance Dx is equal to or more than the threshold value. The development amount of the fracture is reliably increased to improve the processing speed.

Furthermore, in the laser processing device 1, the input reception unit 63 receives the input of the distance Dx in the second processing before the second processing. Before the second processing, in a case where the second input value that is the input value of the distance Dx received by the input reception unit 63 is more than the second threshold value, the control unit 6 causes the input reception unit 63 to display information for urging confirmation of the second input value. In addition, in a case where the second input value is equal to or less than the second threshold value, the control unit 6 performs the second processing. Therefore, in the second processing, it is secured that the distance Dx between the first converging point C1 and the second converging point C2 is equal to or less than the threshold value, and the processing quality is reliably improved.

The above embodiment describes an embodiment of the present disclosure. Thus, the present disclosure is not limited to the above-described form, and any modification can be made.

For example, in the operation of the laser processing device 1 illustrated in FIG. 6, in both the first processing and the second processing, at least the input of the distance Dx is received, and the branch pattern corresponding to the received distance Dx is set and displayed on the spatial light modulator 32. However, the branch pattern may be automatically set. That is, the laser processing device 1 can automatically set the branch pattern in each of the first processing and the second processing and perform the first processing and the second processing, such that the distance Dx in the first processing is relatively larger than the distance Dx in the second processing (in other words, the distance Dx in the second processing is relatively smaller than the distance Dx in the first processing).

In the above embodiment, the case where the laser light L is branched into the two beams of laser light L1 and L2 to form the first converging point C1 and the second converging point C2 has been described. However, in the laser processing device 1, the laser light L may be branched into three or more beams of laser light to form respective converging points. In this case, the relationship of the distance Dx in the first processing>the distance Dx in the second processing may be satisfied for two converging points among three or more converging points.

Furthermore, in the above embodiment, it is assumed that the line M1 extends on the boundary between the effective region R, which is a device region where the functional element is formed, and the removal region E outside the effective region R. However, the line M1 may be set on a boundary between a region wider than the device region as described above (a region obtained by enlarging the effective region R described above to the removal region E side) and a region further outside the region. In addition, the line M1 may be set on a boundary between any first portion and second portion of the object 11 regardless of the effective region R and the removal region E.

### INDUSTRIAL APPLICABILITY

There are provided a laser processing device and a laser processing method capable of achieving both improvement in processing speed and suppression of degradation in processing quality.

### REFERENCE SIGNS LIST

1 laser processing device
2 stage (support)
3 laser irradiation unit
4, 5 drive unit (moving mechanism)
6 control unit
11 object
63 input reception unit (input unit, display unit)
C1 first converging point
C2 second converging point
Dx distance
L, L1, L2 laser light
M1 line (first line)
M2 line (second line)

1. A laser processing device that forms a modified region by irradiating an object with laser light, the laser processing device comprising:
a support configured to support the object;
a laser irradiation unit configured to irradiate the object supported by the support with the laser light while forming a first converging point of the laser light and a second converging point of the laser light located closer to an incident surface side of the laser light in the object than the first converging point;
a moving mechanism configured to move at least one of the support and the laser irradiation unit to relatively move the first converging point and the second converging point with respect to the object; and
a control unit configured to control the laser irradiation unit and the moving mechanism, wherein
the object includes a first portion located on an inner side of the object and a second portion located on an outer side of the first portion and including an outer edge of the object, when viewed from a direction intersecting with the incident surface,
in the object, when viewed from the direction intersecting with the incident surface, a first line annularly extending on a boundary between the first portion and the second portion and a second line extending from the outer edge of the object to the inner side of the object in the second portion and reaching the boundary are set, and
the control unit performs
first processing of controlling the laser irradiation unit and the moving mechanism to irradiate the object with the laser light while relatively moving the first converging point and the second converging point along the first line, in a state where a distance between the first converging point and the second converging point in a direction along the first line is set to a first distance, and
second processing of controlling the laser irradiation unit and the moving mechanism to irradiate the object with the laser light while relatively moving the first converging point and the second converging point along the second line, in a state where a distance between the first converging point and the second converging point in a direction along the second line is set to a second distance smaller than the first distance.

2. The laser processing device according to claim 1, wherein
the control unit performs the second processing a plurality of times while changing a position of the first converging point and a position of the second converging point in the direction intersecting with the incident surface with respect to one of the second lines.

3. The laser processing device according to claim 2, wherein
the control unit performs the n-th second processing (n is an integer of 1 or more), and then performs the m-th second processing (m is an integer more than n) in a state where at least one of the first converging point and the second converging point is located at a position between the first converging point and the second converging point in a direction intersecting with the incident surface in the n-th second processing.

4. The laser processing device according to claim 2, wherein
the control unit performs the n-th second processing (n is an integer of 1 or more), and then performs the (n+1)th second processing in a state where the first converging point is located closer to the incident surface side than the position of the first converging point in a direction intersecting with the incident surface in the n-th second processing.

5. The laser processing device according to claim 1, further comprising:
an input unit configured to receive an input; and
a display unit configured to display information, wherein
the input unit receives an input of the first distance before the first processing, and
the control unit causes the display unit to display information for urging confirmation of a first input value in a case where the first input value is less than a first threshold value before the first processing, the first input value being an input value of the first distance received by the input unit, and performs the first processing in a case where the first input value is equal to or more than the first threshold value.

6. The laser processing device according to claim 5, wherein
the input unit receives an input of the second distance before the second processing, and
the control unit causes the display unit to display information for urging confirmation of a second input value in a case where the second input value is more than a second threshold value before the second processing, the second input value being an input value of the second distance received by the input unit, and performs the second processing in a case where the second input value is equal to or less than the second threshold value.

7. A laser processing method for forming a modified region by irradiating an object with laser light, the laser processing method comprising:
a laser irradiation step of irradiating the object with the laser light while forming a first converging point of the laser light and a second converging point of the laser light located closer to an incident surface side of the laser light in the object than the first converging point, wherein
the object includes a first portion located on an inner side of the object and a second portion located on an outer side of the first portion and including an outer edge of the object, when viewed from a direction intersecting with the incident surface,
in the object, when viewed from the direction intersecting with the incident surface, a first line annularly extending on a boundary between the first portion and the second portion and a second line extending from the outer edge of the object to the inner side of the object in the second portion and reaching the boundary are set, and
the laser irradiation step includes
a first irradiation step of irradiating the object with the laser light while relatively moving the first converging point and the second converging point along the first line, in a state where a distance between the first converging point and the second converging point in a direction along the first line is set to a first distance, and
a second irradiation step of irradiating the object with the laser light while relatively moving the first converging point and the second converging point along the second line, in a state where a distance between the first converging point and the second converging point in a direction along the second line is set to a second distance smaller than the first distance.
